(19) United States
(12) Patent Application Publication
(10) Pub. No.: US 2025/0201668 A1
(43) Pub. Date: Jun. 19, 2025

(54) STRUCTURE AND FORMATION METHOD OF PACKAGE WITH HEAT-SPREADING LID

(71) Applicant: Taiwan Semiconductor Manufacturing Company, Ltd., Hsinchu (TW)

(72) Inventors: Ching Wang, Taichung City (TW); Bang-Li Wu, Hsinchu City (TW); Kuan-Min Wang, Hsinchu City (TW); Kuo-Chin Chang, Chiayi City (TW); Kathy Wei Yan, Hsinchu (TW); Jun He, Zhubei City (TW)

(21) Appl. No.: 18/653,806

(22) Filed: May 2, 2024

Related U.S. Application Data
(60) Provisional application No. 63/611,938, filed on Dec. 19, 2023.

(51) Int. Cl. H01L 23/473; H01L 23/00; H01L 23/427; H01L 23/467

(52) U.S. Cl. CPC H01L 23/473; H01L 23/427; H01L 23/467; H01L 24/13; H01L 24/16; H01L 24/29; H01L 24/32; H01L 24/33; H01L 24/73; H01L 2224/13111; H01L 2224/13116; H01L 2224/13124; H01L 2224/13139; H01L 2224/13147; H01L 2224/16225; H01L 2224/29105; H01L 2224/29109; H01L 2224/29111; H01L 2224/29113; H01L 2224/2929; H01L 2224/29291; H01L 2224/29339; H01L 2224/29344; H01L 2224/29386; H01L 2224/29393; H01L 2224/32245; H01L 2224/33181; H01L 2224/33505; H01L 2224/73204; H01L 2224/73253; H01L 2924/01006; H01L 2924/0542; H01L 2924/0543; H01L 2924/05442; H01L 2924/0655; H01L 2924/0715

(57) ABSTRACT

A package structure and a formation method of a package structure are provided. The package structure includes a chip-containing structure over a substrate and a heat-spreading lid over the chip-containing structure. The package structure also includes a closed chamber embedded in or positioned over the heat-spreading lid. The package structure further includes a cooling pipe partially or completely surrounded by the closed chamber.

### PRIORITY CLAIM AND CROSS-REFERENCE

This Application claims the benefit of U.S. Provisional Application No. 63/611,938, filed on Dec. 19, 2023, the entirety of which is incorporated by reference herein.

### BACKGROUND

The semiconductor integrated circuit (IC) industry has experienced rapid growth. Continuing advances in semiconductor manufacturing processes have resulted in semiconductor devices with finer features and/or higher degrees of integration. Functional density (i.e., the number of interconnected devices per chip area) has generally increased while feature sizes (i.e., the smallest component that can be created using a fabrication process) have decreased. This scaling-down process generally provides benefits by increasing production efficiency and lowering associated costs.

A package structure not only provides protection for semiconductor devices from environmental contaminants, but also provides a connection interface for the semiconductor devices packaged therein. Smaller package structures, which take up less space or are lower in height, have been developed to package the semiconductor devices.

New packaging technologies have been developed to further improve the density and functionality of semiconductor dies. These relatively new types of packaging technologies for semiconductor dies face manufacturing challenges. For example, the heat dissipation of the package structure becomes more important.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1C are cross-sectional views of various stages of a process for forming a portion of a package structure, in accordance with some embodiments.

FIG. 2 is a perspective view of a portion of a package structure, in accordance with some embodiments.

FIG. 3 is a perspective view of a portion of a package structure, in accordance with some embodiments.

FIG. 4 is a cross-sectional view of a portion of a package structure, in accordance with some embodiments.

FIG. 5 is a cross-sectional view of a portion of a package structure, in accordance with some embodiments.

FIG. 6 is a cross-sectional view of a portion of a package structure, in accordance with some embodiments.

FIG. 7A is a cross-sectional view of a portion of a package structure, in accordance with some embodiments.

FIG. 7B is a perspective view of a portion of a package structure, in accordance with some embodiments.

FIG. 8 is a cross-sectional view of a portion of a package structure, in accordance with some embodiments.

FIG. 9 is a cross-sectional view of a portion of a package structure, in accordance with some embodiments.

FIG. 10 is a cross-sectional view of a portion of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher of what is specified, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10 degrees. The word “substantially” does not exclude “completely” e.g. a composition which is “substantially free” from Y may be completely free from Y.

Terms such as “about” in conjunction with a specific distance or size are to be interpreted so as not to exclude insignificant deviation from the specified distance or size and may include for example deviations of up to 10%. The term “about” in relation to a numerical value x may mean x±5 or 10%.

Some embodiments of the disclosure are described. Additional operations can be provided before, during, and/or after the stages described in these embodiments. Some of the stages that are described can be replaced or eliminated for different embodiments. Additional features can be added to the semiconductor device structure and/or the package structure. Some of the features described below can be replaced or eliminated for different embodiments. Although some embodiments are discussed with operations performed in a particular order, these operations may be performed in another logical order.

Embodiments of the disclosure may relate to three-dimensional (3D) packaging or 3D-IC devices. Other features and processes may also be included. For example, testing structures may be included to aid in the verification testing of the 3D packaging or 3D-IC devices. The testing structures may include, for example, test pads formed in a redistribution layer or on a substrate that allows the testing of the 3D packaging or 3D-IC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

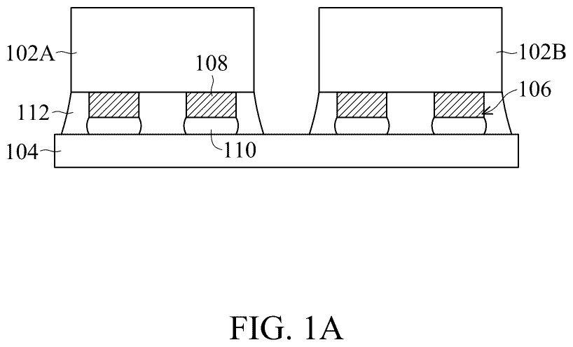

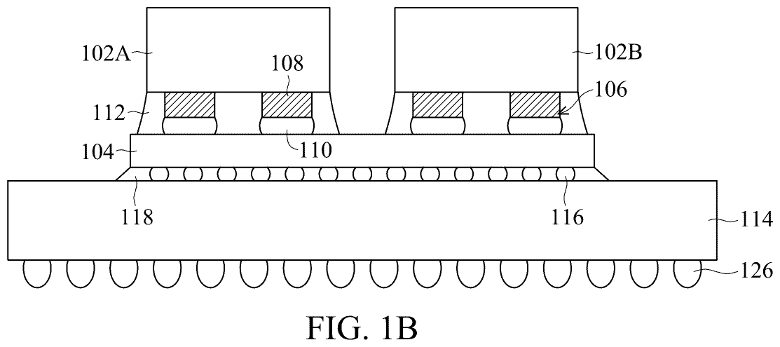

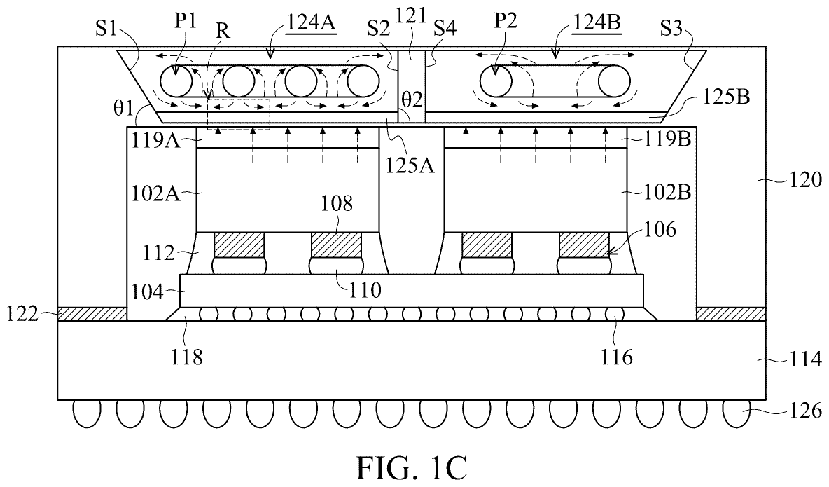

FIGS. 1A-1C are cross-sectional views of various stages of a process for forming a portion of a package structure, in accordance with some embodiments. As shown in FIG. 1A, multiple chip-containing structures 102A and 102B are disposed over a semiconductor interposer 104, in accordance with some embodiments. The chip-containing structures 102A and 102B are laterally spaced apart from each other. In some embodiments, the chip-containing structures 102A and 102B are bonded onto the semiconductor interposer 104 through multiple conductive bonding structures 106.

Each of the conductive bonding structures 106 may include a conductive pillar 108 and a solder bump 110. The conductive pillar 108 may be a copper pillar. The solder bump 110 may be a tin-containing solder bump. The solder bump 110 may include tin and other materials such as copper, silver, gold, aluminum, lead, another suitable material, or a combination thereof. In some embodiments, the solder bumps 110 are lead-free solder bumps.

In some embodiments, the chip-containing structure 102A generates greater heat than the chip-containing structure 102B during operation. In some embodiments, the chip-containing structure 102A is a logic control chip structure that includes multiple logic control device elements. In some embodiments, the chip-containing structure 102A has high power input request of high performance computing (HPC).

The chip-containing structure 102A may include a semiconductor substrate portion, a device portion, and an interconnection structure. The semiconductor substrate portion may include silicon or other elementary semiconductor materials such as germanium. In some embodiments, the semiconductor substrate portion includes an epitaxially grown semiconductor layer on a dielectric layer. The epitaxially grown semiconductor layer may be made of silicon germanium, silicon, germanium, one or more other suitable materials, or a combination thereof.

In some other embodiments, the semiconductor substrate portion includes a compound semiconductor. For example, the compound semiconductor includes one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions. Each of them is greater than or equal to zero, and added together they equal 1. The compound semiconductor may include silicon carbide, gallium arsenide, indium arsenide, indium phosphide, one or more other suitable compound semiconductors, or a combination thereof. Other suitable substrate including II-VI compound semiconductors may also be used.

Multiple device elements are formed in and/or on the device portion of the chip-containing structure 102A. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

In some embodiments, the interconnection structure of the chip-containing structure 102A is formed on the device portion for providing electrical connections to the device elements. The interconnection structure may be a frontside interconnection structure. The interconnection structure includes multiple conductive features that are surrounded by multiple dielectric layers. The conductive features may include conductive contacts, conductive lines, and conductive vias. The formation of the interconnection structure may involve multiple deposition processes, multiple patterning processes, and multiple planarization processes.

The device elements in the device portion of the chip-containing structure 102A may be interconnected by the interconnection structure to form multiple integrated circuit devices such as analog-to-digital converter (ADC) elements, cache elements, global buffer elements, accumulator elements, local buffer elements, activation elements, pooling elements, input and/or output elements, or the like.

The chip-containing structure 102A may be a single semiconductor die, system-on-integrated-chips (SoIC), and/or a package including one or more semiconductor dies that are encapsulated or protected. For the system-on-integrated-chips, multiple semiconductor dies (or chiplets) are stacked and bonded together to form electrical connections between these semiconductor dies. In some embodiments, the semiconductor dies are system-on-chip (SoC) chips that include multiple functions. In some embodiments, the back sides of the semiconductor dies face upwards with the front sides of the semiconductor dies facing the semiconductor interposer 104.

In some embodiments, the chip-containing structure 102B is a memory-containing chip structure that includes multiple memory device elements. In some embodiments, the chip-containing structure 102B includes memory devices such as high bandwidth memory (HBM) devices. In some embodiments, the memory device elements are non-volatile memory elements such as static random access memory (SRAM) elements, resistive random access memory (RRAM) elements, magnetoresistive random access memory (MRAM) elements, or the like.

Multiple device elements are formed in the device portion of the chip-containing structure 102B. Examples of the various device elements include transistors (e.g., metal oxide semiconductor field effect transistors (MOSFET), complementary metal oxide semiconductor (CMOS) transistors, bipolar junction transistors (BJT), or another suitable element. Various processes may be used to form the various device elements, including deposition, etching, implantation, photolithography, annealing, and/or other suitable processes.

The chip-containing structure 102B may be a single semiconductor die, system-on-integrated-chips (SoIC), and/or a package including one or more semiconductor dies that are encapsulated or protected. For the system-on-integrated-chips, multiple semiconductor dies (or chiplets) are stacked and bonded together to form electrical connections between these semiconductor dies. In some embodiments, multiple memory dies are stacked to form a high bandwidth memory (HBM) chip structure.

The semiconductor interposer 104 may include a semiconductor substrate and multiple conductive features. The semiconductor substrate may be made of or include silicon. The conductive features may include through substrate vias (TSVs) that extend into or penetrate through the semiconductor substrate. In some embodiments, one or more dielectric layers surrounding the conductive features are formed to prevent short circuiting between the conductive features.

In some embodiments, interconnection structures are formed over the opposite surfaces of the semiconductor substrate of the semiconductor interposer 104. The interconnection structures may include multiple dielectric layers and multiple conductive features. In some embodiments, the conductive bonding structures 106 are electrically connected to some of the conductive features of the interconnection structure.

As shown in FIG. 1A, underfill structures 112 are formed over the semiconductor interposer 104 to laterally surround and protect the conductive bonding structures 106, in accordance with some embodiments. The underfill structure 112 may be made of or include an epoxy-based resin with fillers dispersed therein. The fillers may include fibers (such as silica fibers and/or carbon-containing fibers), particles (such as silica particles and/or carbon-containing particles), or a combination thereof.

In some embodiments, an underfill liquid is dispensed onto the semiconductor interposer 104 along a side of the chip-containing structure 102A and a side of the chip-containing structure 102B. The underfill liquid may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof.

The underfill liquid may be drawn into the space between the chip-containing structures 102A and 102B and the semiconductor interposer 104, so as to surround the conductive bonding structures 106 by the capillary force. Afterwards, a thermal operation may be used to cure the underfill liquid. As a result, the underfill structures 112 are formed.

As shown in FIG. 1B, the semiconductor interposer 104 is then bonded to the substrate 114 through multiple conductive connectors 116, in accordance with some embodiments. In some embodiments, the conductive connectors 116 are tin-containing solder bumps. The material of the conductive connectors 116 may be the same as or similar to that of the solder bumps 110.

The substrate 114 may be a circuit substrate (or a package substrate). In some embodiments, the substrate 114 includes a core portion. The substrate 114 may further includes multiple insulating layers and multiple conductive features. The conductive features may be used to route electrical signals between opposite sides of the substrate 114. The insulating layers may be made of or include one or more polymer materials. The conductive features may be made of or include copper, aluminum, cobalt, tungsten, gold, one or more other suitable materials, or a combination thereof.

The core portion of the substrate 114 may include organic materials such as materials that can be easily laminated. In some embodiments, the core portion may include a single-sided or double-sided copper clad laminate, epoxy, resin, glass fiber, molding compound, plastic (such as polyvinylchloride (PVC), acrylonitrile, butadiene and styrene (ABS), polypropylene (PP), polyethylene (PE), polystyrene (PS), polymethyl methacrylate (PMMA), polyethylene terephthalate (PET), polycarbonates (PC), polyphenylene sulfide (PPS)), one or more other suitable elements, or a combination thereof. Conductive vias may extend through the core portion to provide electrical connections between elements disposed on either side of the core portion.

In some embodiments, the substrate 114 further includes conductive bonding structures 126. In some embodiments, the conductive bonding structures 126 are solder bumps. In some embodiments, the conductive bonding structures 126 are used for bonding with another element such as a printed circuit board.

In some embodiments, the conductive bonding structures 126 are lead-free solder bumps. In some embodiments, each of the conductive bonding structures 126 is wider than each of the conductive connectors 116. In some embodiments, the pitch between the conductive bonding structures 126 is wider than the pitch between the conductive connectors 116.

As shown in FIG. 1B, an underfill structure 118 is formed over the substrate 114 to laterally surround and protect the conductive connectors 116, in accordance with some embodiments. The material and formation method of the underfill structure 118 may be the same as or similar to those of the underfill structures 112.

As shown in FIG. 1C, a heat-spreading lid (or a heat spreader) 120 is disposed over the chip-containing structures 102A and 102B, in accordance with some embodiments. In some embodiments, the heat-spreading lid 120 is attached to the chip-containing structures 102A and 102B through thermal conductive layers 119A and 119B. In some embodiments, the heat-spreading lid 120 is further attached to the substrate 114 through adhesive layers 122.

Each of the thermal conductive layers 119A and 119B function as a thermal interface material. The thermal conductive layers 119A and 119B may be made of or include a polymer material including silicone or epoxy. The thermal conductive layers 119A and 119B may further contain particles dispersed in the polymer material. The particles may be made of or include dielectric particles such as aluminum oxide and/or zinc oxide, metal particles such as gold and/or silver, other suitable particles, or a combination thereof.

In some other embodiments, the thermal conductive layers 119A and 119B are made of or include a solid material or a liquid material. The solid material may include tin (Sn), Indium (In), Bismuth (Bi), another suitable material, an alloy thereof, or a combination thereof. The liquid material may include gallium (Ga), alloys thereof, or a resin material containing gallium (Ga) or alloys thereof.

The heat-spreading lid 120 may help to improve the heat dissipation of the chip-containing structures 102A and 102B, so as to improve the operation and reliability of the chip-containing structures 102A and 102B. In some embodiments, the heat-spreading lid 120 is made of or includes one or more metal materials.

The heat-spreading lid 120 may be made of or include copper, nickel, aluminum, gold, silver, steel, another suitable material, or a combination thereof. In some embodiments, the heat-spreading lid 120 has a main body that is made of or include copper. The heat-spreading lid 120 may further have one or more other layers coated on the main body. For example, these layers may include an inner layer made of nickel and one or more outer layers that are made of gold and/or silver.

As shown in FIG. 1C, multiple closed chambers 124A and 124B are formed in the heat-spreading lid 120, in accordance with some embodiments. The closed chambers 124A and 124B are embedded in the heat-spreading lid 120. In some embodiments, the closed chambers 124A and 124B are isolated from the outside environment. In some embodiments, the closed chambers 124A and 124B are closer to the chip-containing structures 102A and 102B than the topmost surface of the heat-spreading lid 120. In some embodiments, the substrate 114 is wider than each of the closed chambers 124A and 124B, as shown in FIG. 1C. In some embodiments, the closed chambers 124A and 124B occupy smaller space than the heat-spreading lid 120.

In some embodiments, the heat-spreading lid 120 has a wall structure 121 that is between the closed chambers 124A and 124B. In some embodiments, the closed chambers 124A and 124B are isolated from each other by the wall structure 121. In some embodiments, the closed chamber 124A is directly above the chip-containing structure 102A, and the closed chamber 124B is directly above the chip-containing structure 102B. In some embodiments, the closed chamber 124A extends across the opposite sidewalls of the chip-containing structure 102A, and the closed chamber 124B extends across the opposite sidewalls of the chip-containing structure 102B.

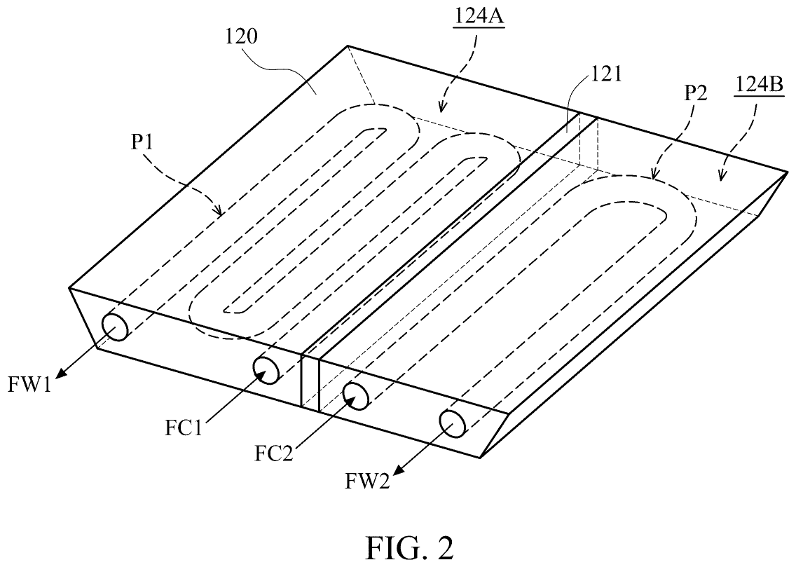

FIG. 2 is a perspective view of a portion of a package structure, in accordance with some embodiments. In some embodiments, FIG. 2 shows the perspective view of a portion of the heat-spreading lid 120 shown in FIG. 1C. As shown in FIGS. 1C and 2, a cooling pipe P1 is partially or completely surrounded by the closed chamber 124A, in accordance with some embodiments. In some embodiments, the cooling pipe P1 extends across the opposite sidewalls of the chip-containing structure 102A. In some embodiments, a cooling pipe P2 is partially or completely surrounded by the closed chamber 124B, as shown in FIGS. 1C and 2. The diameter of the cooling pipe P1 or P2 may be within a range from about 0.05 mm to about 0.2 mm. The height of the closed chamber 124A or 124B may be within a range from about 0.3 mm to about 0.5 mm. In some embodiments, the chip-containing structure 102A or 102B is higher than the closed chamber 124A or 124B. In some other embodiments, the chip-containing structure 102A or 102B is substantially as high as the closed chamber 124A or 124B.

The cooling pipes P1 and P2 may function as cooling network structures. The cooling pipes P1 and P2 may allow a cooling material such as a cooling liquid to flow in the cooling pipes P1 and P2. As a result, the surfaces of the cooling pipes P1 and P2 may be kept at a low temperature while the cooling liquid flows in the cooling pipes P1 and P2. The cooling liquid may include water, silicon oil, mineral oil, fluorine-containing liquid, dielectric liquid, liquid nitrogen, another suitable cooling liquid, or a combination thereof. The temperature of the cooling liquid that is introduced into the cooling pipes P1 and P2 may have a temperature that is in a range from about 0.1 degrees C. to about 25 degrees C.

However, embodiments of the disclosure are not limited thereto. Many variations and/or modifications can be made to embodiments of the disclosure. In some other embodiments, cooling gas is introduced into the cooling pipe P1 and P2. The cooling gas flowing in the cooling pipes P1 and P2 may also help to keep the surfaces of the cooling pipes P1 and P2 with a low temperature. The cooling gas may include nitrogen, argon, another suitable cooling gas, or a combination thereof.

In some other embodiments, another cooling network structure other than the cooling pipe is used. In some embodiments, the cooling network structure includes a solid mesh structure that is in direct contact with another cooling source.

In some embodiments, phase-changing elements such as liquid materials 125A and 125B are respectively introduced into the closed chambers 124A and 124B, as shown in FIG. 1C. In some embodiments, each of the liquid materials 125A and 125B is made of or includes water. The operation temperature of water may be within a range from about 298K to about 573K. In some other embodiments, based on different operation temperature, the liquid materials 125A and/or 125B are made of or include ammonia solution, perfluorinated compound (PFC), methanol, ethanol, liquid helium, another suitable material, or a combination thereof. The operation temperature of the ammonia solution may be within a range from about 213K to about 373K. The operation temperature of the perfluorinated compound may be within a range from about 233K to about 398K. The operation temperature of methanol may be within a range from about 283K to about 403K. The operation temperature of ethanol may be within a range from about 273K to about 403K. For super low temperature application, liquid helium may be used as the liquid materials 125A and/or 125B. The operation temperature of liquid helium may be within a range from about 2K to about 4K. In some embodiments, the liquid materials 125A and 125B are positioned on the bottom surfaces of the closed chambers 124A and 124B, respectively. In some embodiments, the liquid materials 125A and 125B are spaced apart from the cooling pipes P1 and P2. The vertical distance between the top of the liquid material 125A and the bottom of the cooling pipe P1 may be within a range from about 0.05 mm to about 0.1 mm.

In some embodiments, during the operation of the chip-containing structures 102A and 102B, heat generated from the chip-containing structures 102A and 102B is led to the liquid materials 125A and 125B through the thermal conductive layers 119A and 119B and the heat-spreading lid 120. As a result, the heat from the chip-containing structures 102A and 102B induces the evaporation of the liquid materials 125A and 125B.

In some embodiments, each of the liquid materials 125A and 125B is made of water. Evaporation and condensation processes may be involved in the water cycle of the liquid materials 125A and 125B. Evaporation converts the water into water vapor. Condensation cools down the water vapor and converts it back to water droplets.

In some embodiments, the water vapor generated from the evaporation of the liquid materials 125A and 125B may reach the surfaces of the cooling pipes P1 and P2 with a low temperature. As a result, the water vapor that carries the heat from the chip-containing structures 102A and 102B may be cooled and condensed into water at the top surface of the heat-spreading lid 120 and the surfaces of the cooling pipes P1 and P2. The condensed water with a lower temperature may then flow to the bottoms of the closed chambers 124A and 124B along the sidewalls of the closed chambers 124A and 124B. Due to the condensed water that is cooler, the liquid materials 125A and 125B may be kept at a low temperature and continue to improve the heat dissipation of the chip-containing structures 102A and 102B.

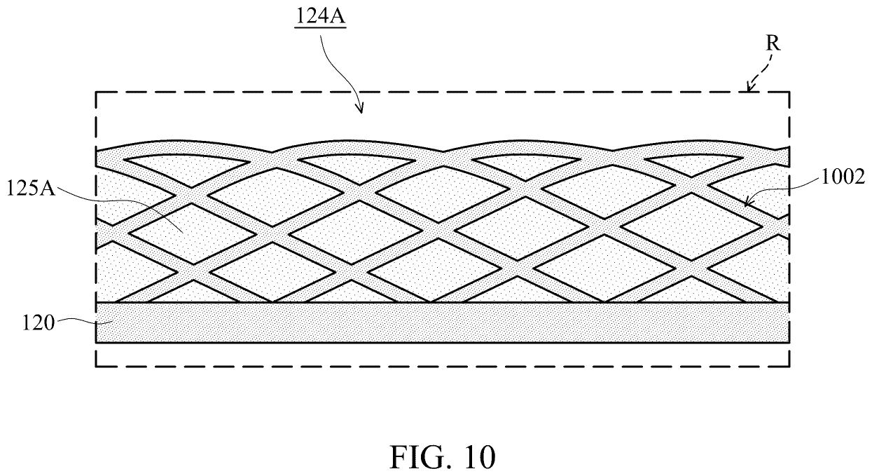

FIG. 10 is a cross-sectional view of a portion of a package structure, in accordance with some embodiments. In some embodiments, FIG. 10 shows the cross-sectional view of the region R in FIG. 1C. As shown in FIG. 10, a wick structure 1002 is formed in the closed chamber, in accordance with some embodiments. In some embodiments, the wick structure 1002 is formed on the bottom surface of the closed chamber 124A. The wick structure 1002 between the chip-containing structure 102A and the cooling pipe P1 is capable of conveying liquid by capillary action. Due to the capillary action, the liquid material 125A may be spread on the surfaces of the wick structure 1002, which improves the evaporation of the liquid material 125A. The heat dissipation efficiency of the heat-spreading is thus significantly improved.

As shown in FIG. 1C, the closed chamber 124A has sidewalls S1 and S2, and the closed chamber 124B has sidewalls S3 and S4. In some embodiments, the sidewalls S1 and S3 are inclined sidewalls. In some embodiments, the inclined profiles of the sidewalls S1 and S3 may help to accelerate the condensed water to flow back to the liquid materials 125A and 125B along the sidewalls S1 and S3. The high heat removal capability of the heat-spreading lid 120 may thus be ensured.

As shown in FIG. 1C, the sidewall S1 of the closed chamber 124A and a lower surface of the heat-spreading lid 120 extending along a direction away from the closed chamber 124A form an angle Θ1. In some embodiments, the angle 1 is an acute angle. The angle Θ1 may be in a range from about 30 degrees to about 70 degrees. In some embodiments, the angle Θ1 is about 60 degrees.

In some cases, if the angle Θ1 is too large (such as larger than about 70 degrees) or too small (such as smaller than about 30 degrees), the gathering of the condensed water may become relatively difficult. The condensed water may flow back to the liquid material 125A at a lower speed. The heat dissipation efficiency of the heat-spreading lid 120 might be adversely impacted.

As shown in FIG. 1C, the sidewall S2 of the wall structure 121 and a lower surface of the heat-spreading lid 120 extending along a direction away from the closed chamber 124A form an angle Θ2. The angle Θ2 may be in a range from about 45 degrees to about 90 degrees. In some cases, if the angle Θ2 is too small (such as smaller than about 45 degrees), the closed chamber 124A may occupy too large area. The structural strength of the wall structure 121 might also be adversely impacted.

In some embodiments, the cooling pipe P1 surrounded by the closed chamber 124A and the cooling pipe P2 surrounded by the closed chamber 124B have different designs, as shown in FIGS. 1C and 2. In some embodiments, the cooling pipe P1 is designed to have a better cooling ability than the cooling pipe P2 since the cooling pipe P1 is disposed over the chip-containing structure 102A that generates more heat than the chip-containing structure 102B. In some embodiments, the cooling pipe P1 occupies larger space than the cooling pipe P2, as shown in FIGS. 1C and 2.

In some embodiments, the cooling liquid flowing in the cooling pipe P1 has a lower temperature than the cooling liquid flowing in the cooling pipe P2. In some embodiments, the material of the cooling liquid flowing in the cooling pipe P1 and the material of the cooling liquid flowing in the cooling pipe P2 are different. In some embodiments, the material of the cooling liquid flowing in the cooling pipe P1 and the material of the cooling liquid flowing in the cooling pipe P2 are the same.

In some embodiments, the flow rate of the cooling liquid flowing in the cooling pipe P1 is different than the flow rate of the cooling liquid flowing in the cooling pipe P2. In some embodiments, the flow rate of the cooling liquid flowing in the cooling pipe P1 is higher than the flow rate of the cooling liquid flowing in the cooling pipe P2. In some embodiments, the pipe diameter of the cooling pipe P1 is larger than the pipe diameter of the cooling pipe P2. In some embodiments, the cooling pipe P1 has more bend sections than the cooling pipe P2, as shown in FIG. 2.

In some embodiments, the cooling pipe P1 has an inlet FC1 allowing the cooling liquid or cooling gas to flow into the portion of the cooling pipe P1 surrounded by the closed chamber 124A, as shown in FIG. 2. The cooling pipe P1 also has an outlet FW1 allowing the cooling liquid or cooling gas that may become warmer to flow out of the portion of the cooling pipe P1 surrounded by the closed chamber 124A. Similarly, the cooling pipe P2 also has an inlet FC2 and an outlet FW2, as shown in FIG. 2 in accordance with some embodiments.

In some embodiments, the inlet FC1 of the cooling pipe P1 is positioned between the outlet FW1 and the closed chamber 124B, as shown in FIG. 2. The inlet FC2 of the cooling pipe P2 is positioned between the inlet FC1 of the cooling pipe P1 and the outlet FW2 of the cooling pipe P2. In some embodiments, the inlets FC1 and FC2 where the introduced cooling liquid or cooling gas flows into are positioned next to each other, as shown in FIG. 2.

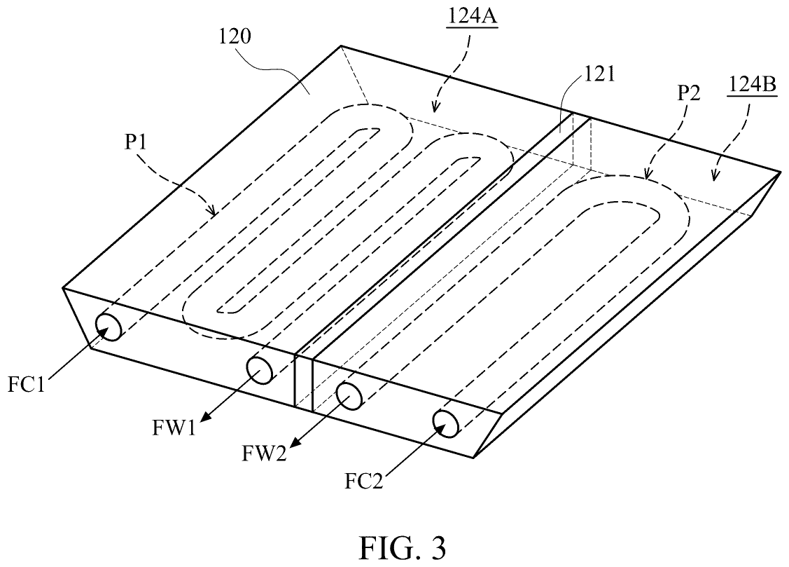

However, embodiments of the disclosure are not limited thereto. Many variations and/or modifications can be made to embodiments of the disclosure. FIG. 3 is a perspective view of a portion of a package structure, in accordance with some embodiments. In some embodiments, FIG. 3 shows the perspective view of a portion of the heat-spreading lid 120 shown in FIG. 1C. In some embodiments, the outlet FW1 of the cooling pipe P1 is positioned between the inlet FC1 and the closed chamber 124B, as shown in FIG. 3. The outlet FW2 of the cooling pipe P2 is positioned between the outlet FW1 of the cooling pipe P1 and the inlet FC2 of the cooling pipe P2.

In some embodiments, multiple closed chambers are positioned directly above different chip-containing structures. However, embodiments of the disclosure are not limited thereto. Many variations and/or modifications can be made to embodiments of the disclosure. In some other embodiments, a single closed chamber that extends across multiple chip-containing structures is formed.

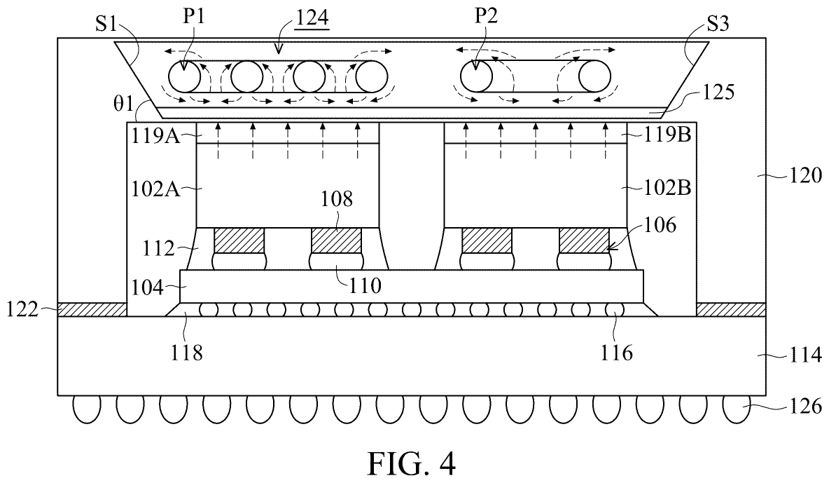

FIG. 4 is a cross-sectional view of a portion of a package structure, in accordance with some embodiments. In some embodiments, a closed chamber 124 that extends across the chip-containing structures 102A and 102B is embedded in the heat-spreading lid 120. There is no wall structure formed between the cooling pipes P1 and P2. The cooling pipes P1 and P2 are positioned in the same closed chamber 124.

In some embodiments, the closed chamber 124 extends across the opposite sidewalls of the chip-containing structure 102A and the opposite sidewalls of the chip-containing structure 102B. In some embodiments, the cooling pipes P1 and P2 that have different designs are disposed directly above the chip-containing structures 102A and 102B, respectively. The temperature of the cooling pipes P1 and P2 may be fine-tuned according to the requirements, so as to improve the total heat dissipation efficiency of the heat-spreading lid 120. As a result, the performance and reliability of the chip-containing structures 102A and 102B are greatly improved.

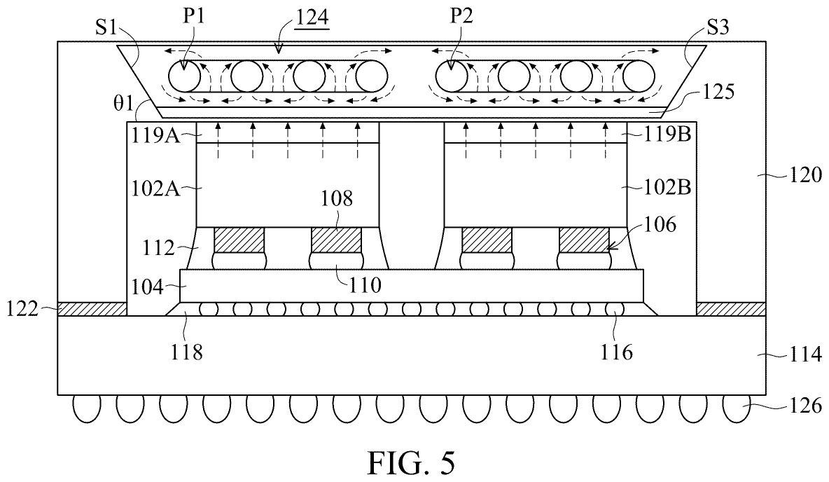

Many variations and/or modifications can be made to embodiments of the disclosure. FIG. 5 is a cross-sectional view of a portion of a package structure, in accordance with some embodiments. In some embodiments, the cooling pipes P1 and P2 that have the same design are disposed directly above the chip-containing structures 102A and 102B, respectively. In some embodiments, the temperature of the cooling pipes P1 and P2 are kept the same. In some other embodiments, the temperature of the cooling pipes P1 and P2 may be fine-tuned according to the requirements, so as to improve the total heat dissipation efficiency of the heat-spreading lid 120. As a result, the performance and reliability of the chip-containing structures 102A and 102B are greatly improved.

In some embodiments, there is only a single cooling pipe partially or completely surrounded by a closed chamber. However, embodiments of the disclosure are not limited thereto. Many variations and/or modifications can be made to embodiments of the disclosure. In some other embodiments, two or more cooling pipes are partially or completely surrounded by a closed chamber.

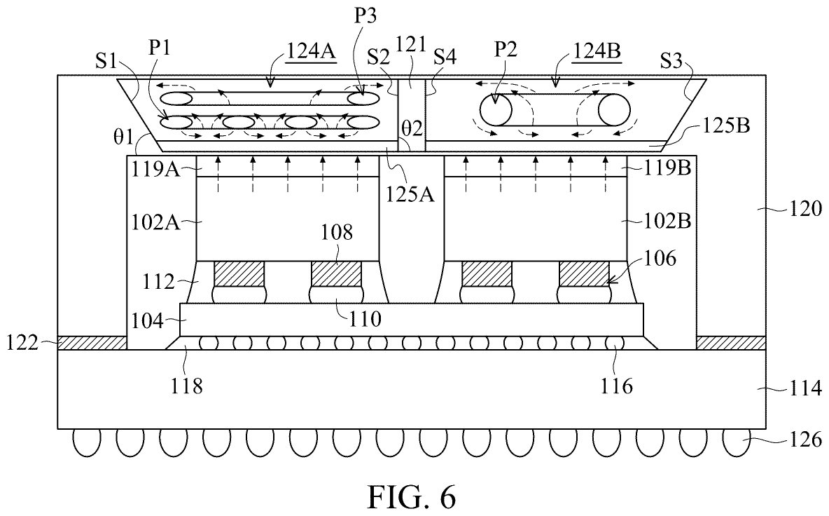

FIG. 6 is a cross-sectional view of a portion of a package structure, in accordance with some embodiments. In some embodiments, in addition to the cooling pipe P1, a cooling pipe P3 is provided. The cooling pipe P3 is partially or completely surrounded by the closed chamber 124A. In some embodiments, during operation, the cooling pipes P1 and P3 have different temperature. In some embodiments, the cooling ability of the cooling pipe P1 is better than the cooling pipe P3. In some embodiments, during operation, the cooling pipe P1 has a lower temperature than the cooling pipe P3, which may facilitate the water cycle of the liquid material 125A.

In some embodiments, the cooling pipes P1 and P3 have different designs. In some embodiments, the cooling pipe P1 occupies larger space than the cooling pipe P3. In some embodiments, the cooling liquid flowing in the cooling pipe P1 has a lower temperature than the cooling liquid flowing in the cooling pipe P3. In some embodiments, the material of the cooling liquid flowing in the cooling pipe P1 and the material of the cooling liquid flowing in the cooling pipe P3 are different. In some embodiments, the material of the cooling liquid flowing in the cooling pipe P1 and the material of the cooling liquid flowing in the cooling pipe P3 are the same. In some embodiments, the flow rate of the cooling liquid flowing in the cooling pipe P1 is higher than the flow rate of the cooling liquid flowing in the cooling pipe P3. In some embodiments, the pipe diameter of the cooling pipe P1 is larger than the pipe diameter of the cooling pipe P3. In some embodiments, the cooling pipe P1 has more bend sections than the cooling pipe P3.

The temperate and/or flow rate of the cooling liquid or cooling air flowing in the cooling pipe may be fine-tuned, so as to ensure efficient water cycle of the liquid material within the closed chamber. The heat dissipation efficiency of the heat-spreading lid may thus be improved. Many variations and/or modifications can be made to embodiments of the disclosure. In some embodiments, one or more temperature sensors are used to detect the temperature at different portions of the package structure. Based on the information gathered by the temperature sensors, the temperate and/or flow rate of the cooling liquid or cooling air flowing in the cooling pipe may be fine-tuned.

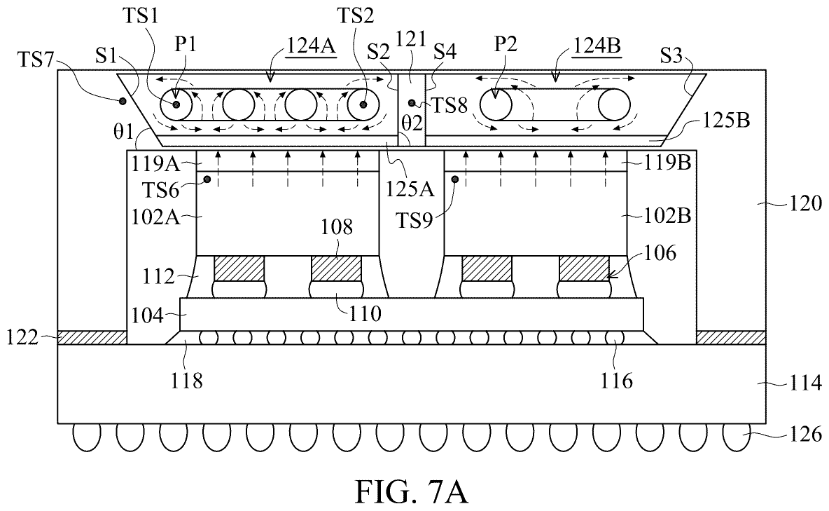

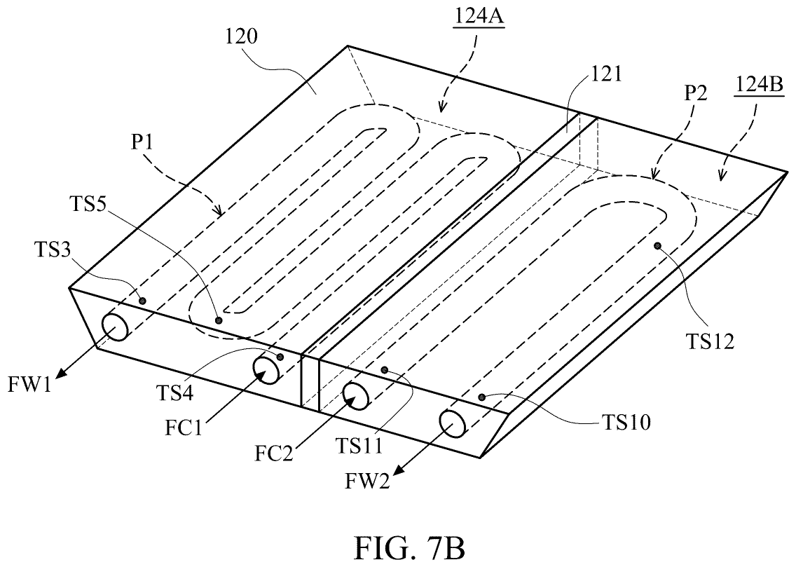

FIG. 7A is a cross-sectional view of a portion of a package structure, in accordance with some embodiments. FIG. 7B is a perspective view of a portion of a package structure, in accordance with some embodiments. In some embodiments, one or more temperature sensors are formed at one or more portions of the package structure, so as to gather the temperature information. As shown in FIGS. 7A and 7B, multiple temperature sensors TS1 to TS12 are set. In some embodiments, only one of the temperature sensors TS1 to TS12 is set. In some other embodiments, two or more of the temperature sensors TS1 to TS12 are set.

In some embodiments, the temperature sensors TS1 to TS5, and TS10 to TS12 are set in or adjacent to the cooling pipes P1 and P2. In some embodiments, the temperature sensors TS4 and TS11 are set in or adjacent to the inlets FC1 and FC2, respectively. In some embodiments, the temperature sensor TS5 is set in or adjacent to the bend section of the cooling pipe P1. In some embodiments, the temperature sensors TS6 and TS9 are set in or adjacent to the chip-containing structures 102A and 102B, respectively. In some embodiments, the temperature sensors TS7 and TS8 are set in or adjacent to the heat-spreader lid 120.

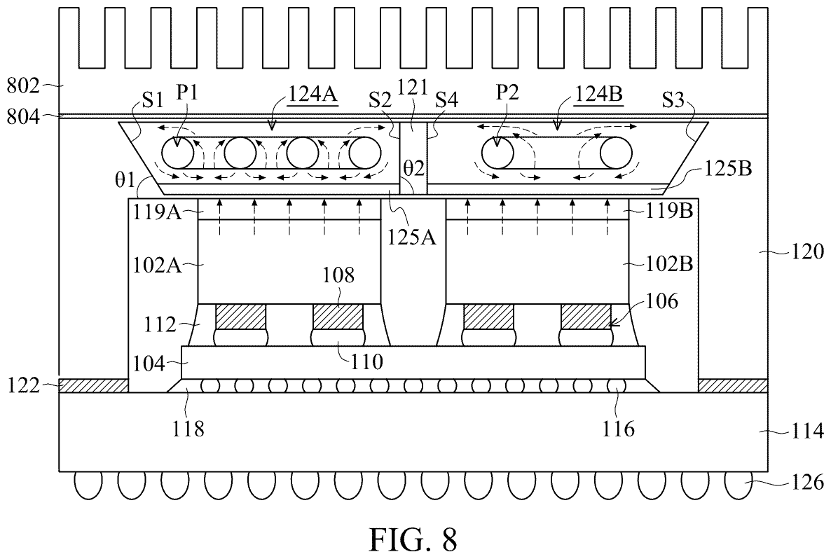

Many variations and/or modifications can be made to embodiments of the disclosure. FIG. 8 is a cross-sectional view of a portion of a package structure, in accordance with some embodiments. A thermal conductive structure 802 is disposed over the heat-spreading lid 120. In some embodiments, the thermal conductive structure 802 extends across the edges of the closed chambers 124A and 124B. The thermal conductive structure 802 may function as a heat sink that help to improve the heat dissipation efficiency of the heat-spreading lid 120. Due to the thermal conductive structure 802, the water cycle of the liquid materials 125A and 125B may be improved further. The operation and reliability of the package structure may thus be improved.

The thermal conductive structure 802 may be made of or include copper, gold, steel, silver, one or more other suitable materials, or a combination thereof. The thermal conductive structure 802 may be attached to the heat-spreading lid 120 using an adhesive layer 804. The adhesive layer 804 may include an adhesive tape, a glue material, or the like. In some embodiments, the adhesive layer 804 is made of a material that is the same as or similar to that of the thermal conductive layers 119A and 119B.

In some embodiments, the closed chamber is embedded in the heat-spreading lid 120. However, embodiments of the disclosure are not limited thereto. Many variations and/or modifications can be made to embodiments of the disclosure. In some other embodiments, the closed chamber is positioned over the heat-spreading lid 120.

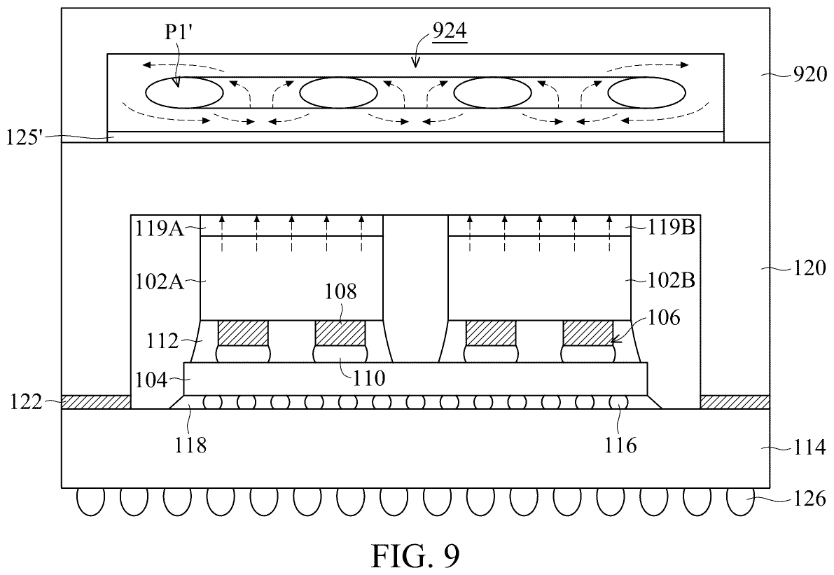

FIG. 9 is a cross-sectional view of a portion of a package structure, in accordance with some embodiments. In some embodiments, a second heat-spreading lid 920 is disposed over the heat-spreading lid 120. The material of the second heat-spreading lid 920 may be the same as or similar to that of the heat-spreading lid 120. In some embodiments, the second heat-spreading lid 920 surrounds a closed chamber 924 over the heat-spreading lid 120.

In some embodiments, a cooling pipe P1′ and a liquid material 125′ are disposed, as shown in FIG. 9. Similar to the cooling pipe P1, the cooling pipe P1′ is partially or completely surrounded by the closed chamber 924. The liquid material 125′ may be made of or include water. Similar to the embodiments illustrated in FIG. 1C, the cooling pipe P1′ may assist in the water cycle of the liquid material 125′, so as to lower the temperature of the heat-spreading lid 120 underneath. As a result, the heat dissipation efficiency of the heat-spreading lid 120 is improved. The performance and reliability of the package structure are ensured.

Embodiments of the disclosure form a package structure with a heat-spreading lid. A closed chamber is formed in or over the heat-spreading lid. A cooling network structure such as a cooling pipe is set to be partially or completely surrounded by the closed chamber. The temperate and/or flow rate of the cooling liquid or cooling air flowing in the cooling pipe may be fine-tuned, so as to adjust the temperature of the cooling pipe and to ensure efficient water cycle of the liquid material within the closed chamber. The heat dissipation efficiency of the heat-spreading lid may thus be improved. Accordingly, the performance and reliability of the package structure are greatly improved.

In accordance with some embodiments, a package structure is provided. The package structure includes a chip-containing structure over a substrate and a heat-spreading lid over the chip-containing structure. The package structure also includes a closed chamber embedded in or positioned over the heat-spreading lid. The package structure further includes a cooling pipe partially or completely surrounded by the closed chamber.

In accordance with some embodiments, a package structure is provided. The package structure includes a chip-containing structure over a substrate and a heat spreader over the chip-containing structure. The package structure also includes a closed chamber embedded in or positioned over the heat spreader. The closed chamber is directly above the chip-containing structure. The package structure further includes a cooling network structure partially or completely surrounded by the closed chamber.

In accordance with some embodiments, a method for forming a package structure is provided. The method includes disposing a chip-containing structure over a substrate. The method also includes disposing a heat-spreading lid over the chip-containing structure. A closed chamber is positioned in or over the heat-spreading lid. A cooling pipe is partially or completely surrounded by the closed chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a chip-containing structure over a substrate;
a heat-spreading lid over the chip-containing structure;
a closed chamber embedded in or positioned over the heat-spreading lid; and
a first cooling pipe at least partially surrounded by the closed chamber.

2. The package structure as claimed in claim 1, further comprising a liquid material in the closed chamber.

3. The package structure as claimed in claim 1, wherein the first cooling pipe extends across opposite sidewalls of the chip-containing structure.

4. The package structure as claimed in claim 1, wherein an inclined sidewall of the closed chamber and a lower surface of the heat-spreading lid extending along a direction away from the closed chamber form an acute angle, and the acute angle is in a range from about 30 degrees to about 70 degrees.

5. The package structure as claimed in claim 1, further comprising a second chip-containing structure over the substrate, wherein the second chip-containing structure is laterally spaced apart from the chip-containing structure, and the chip-containing structure generates greater heat than the second chip-containing structure during operation of the chip-containing structure and the second chip-containing structure.

6. The package structure as claimed in claim 5, further comprising:
a second closed chamber embedded in or positioned over the heat-spreading lid; and
a second cooling pipe at least partially surrounded by the second closed chamber.

7. The package structure as claimed in claim 6, further comprising a wall structure between the closed chamber and the second closed chamber, wherein a sidewall of the wall structure and a lower surface of the heat-spreading lid extending along a direction away from the closed chamber form an angle, and the angle is in a range from about 45 degrees to about 90 degrees.

8. The package structure as claimed in claim 6, wherein:
the first cooling pipe has a first inlet and a first outlet,
the second cooling pipe has a second inlet and a second outlet,
the first inlet is between the first outlet and the second closed chamber, and
the second inlet is between the first inlet and the second outlet.

9. The package structure as claimed in claim 5, wherein the closed chamber extends across opposite sidewalls of the second chip-containing structure, and the package structure further comprises a second cooling pipe at least partially surrounded by the closed chamber, wherein a portion of the second cooling pipe is directly above the second chip-containing structure.

10. The package structure as claimed in claim 1, further comprising a second cooling pipe at least partially surrounded by the closed chamber, wherein the first cooling pipe is between the second cooling pipe and the chip-containing structure.

11. The package structure as claimed in claim 1, further comprising a temperature sensor positioned in or adjacent to the first cooling pipe, the chip-containing structure, or the heat-spreading lid.

12. A package structure, comprising:
a chip-containing structure over a substrate;
a heat spreader over the chip-containing structure;
a closed chamber embedded in or positioned over the heat spreader, wherein the closed chamber is directly above the chip-containing structure; and
a cooling network structure at least partially surrounded by the closed chamber.

13. The package structure as claimed in claim 12, further comprising at least one liquid material on a bottom surface of the closed chamber.

14. The package structure as claimed in claim 12, wherein the cooling network structure is a cooling pipe allowing a cooling liquid or a cooling gas to flow in the cooling pipe.

15. The package structure as claimed in claim 12, wherein the cooling network structure extends across at least one sidewall of the chip-containing structure.

16. The package structure as claimed in claim 12, further comprising a wick structure positioned in the closed chamber, wherein the wick structure is between the chip-containing structure and the cooling network structure, and the wick structure is capable of conveying liquid by capillary action.

17. A method for forming a package structure, comprising:
disposing a chip-containing structure over a substrate; and
disposing a heat-spreading lid over the chip-containing structure, wherein:
a closed chamber is positioned in or over the heat-spreading lid, and
a cooling pipe is at least partially surrounded by the closed chamber.

18. The method for forming the package structure as claimed in claim 17, further comprising disposing at least one liquid material in the closed chamber, wherein the at least one liquid material is outside of the cooling pipe.

19. The method for forming the package structure as claimed in claim 17, further comprising:
disposing the chip-containing structure over a semiconductor interposer; and
disposing the semiconductor interposer carrying the chip-containing structure over the substrate.

20. The method for forming the package structure as claimed in claim 17, further comprising attaching the heat-spreading lid to the substrate.
